(19) United States
(12) Patent Application Publication
(10) Pub. No.: US 2023/0155051 A1
(43) Pub. Date: May 18, 2023

(54) SENSOR, SYSTEM AND METHOD FOR ACQUIRING A SIGNAL INDICATIVE OF AN INTENSITY SPECTRUM OF ELECTROMAGNETIC RADIATION

(71) Applicants: Daozhi SHEN, Waterloo (CA); Adam Wei TSEN, Waterloo (CA)

(72) Inventors: Daozhi SHEN, Waterloo (CA); Adam Wei TSEN, Waterloo (CA)

(21) Appl. No.: 18/055,922

(22) Filed: Nov. 16, 2022

Related U.S. Application Data
(60) Provisional application No. 63/280,177, filed on Nov. 17, 2021.

(51) Int. Cl. H01L 31/113; H01L 31/032; H01L 31/0224

(52) U.S. Cl. CPC H01L 31/1136; H01L 31/032; H01L 31/022466

(57) ABSTRACT

The system can generally have a substrate, a layered structure supported by the substrate, the layered structure including a first layer being of a first material electrically conductive and transparent to said electromagnetic radiation, a second layer being of a second material electrically conductive and having a first photocurrent generation spectrum covering a first band of energy levels, a middle layer of a third material having a second photocurrent generation spectrum covering a second band of the energy levels of the electromagnetic radiation, the second band complementing the first band; the layered structure connected via the first layer and second layer as an electrical component of an electrical circuit of an acquisition module.

### CROSS-REFERENCE TO OTHER APPLICATIONS

The current disclosure claims priority from U.S. Provisional Application No. 63/280,177 filed Nov. 17, 2021, which is hereby incorporated by reference.

### FIELD

The disclosure is generally directed at electromagnetic radiation and, more specifically, is directed at a sensor, system and method for acquiring a signal indicative of an intensity spectrum of electromagnetic radiation.

### BACKGROUND

The field of technologies involving thin layer (e.g. “2D”), layered materials, sometimes referred to as van der Waals materials and/or heterostructures, has been receiving an impressive degree of attention from scientists around the world over recent years. While significant scientific breakthroughs and many new applications have been developed over recent years, there appears to remain constant room for improvement.

In materials science and characterization, for instance, increasing bandwidth and spatial resolution of spectroscopy techniques is a constant challenge, particularly over broader bandwidths and/or below the diffraction limit.

Broadband optical spectroscopies, either as reflectance and absorption, and such as from the infrared (IR) to ultraviolet (UV) can be powerful, noninvasive techniques for characterizing structural, chemical, and/or electronic properties of material compositions. Such optical measurements can be limited by diffraction, however, which imposes a tradeoff between the smallest detectable photon energy and probe area that is given by the relation: illumination spot size ≥λ/2, at a given wavelength λ. This can make applying local spectroscopy in the longer wavelength IR regime especially difficult and impose restrictions on material uniformity which may be so stringent as to be unachievable in practice. Using tip-enhanced near-field techniques may offer lesser restrictions while carrying disadvantages of high cost and low throughput, and simultaneously requiring the use of a broadband source with greater intensity. Another avenue is to obtain local spectroscopic information on non-uniform systems with widefield illumination by instead placing the area of interest in proximal contact to an ultrasmall photodetector. The local absorbance spectrum may then be determined by comparing wavelength-dependent photocurrent measurements taken with and without the sample.

While the latter detection scheme may be easier to implement in some embodiments, it may also place stricter requirements on the capabilities of the detector: broadband response, high sensitivity, fast response speed, and/or miniaturizability may be needed, possibly together with room temperature operability.

Therefore, there is provided a novel sensor, system and method for acquiring a signal indicative of an intensity spectrum of electromagnetic radiation.

### SUMMARY

The current disclosure is directed at a sensor, system and method for acquiring a signal indicative of an intensity spectrum of electromagnetic radiation. In some embodiments, the disclosure includes a sensor that includes a layered van der Waals heterostructure having a transparent conductor, a reactive conductor generating photocurrent in response to a first energy band, and one or more reactive insulators generating photocurrent in response to a second energy band complementing the first energy band, sandwiched between the transparent conductor and the reactive conductor. In this manner, the signal can be acquired by an electrical circuit connecting the transparent conductor and the reactive conductor, for instance.

In one aspect of the disclosure, there is provided a sensor for acquiring a signal indicative of an intensity spectrum of electromagnetic radiation, the sensor including a substrate layer; and a layered sensor layer atop the substrate layer; wherein the layered sensor layer includes: a transparent conductive layer; a photocurrent generation spectrum conductive layer; and at least one middle insulating layer located between the transparent conductive layer and the photocurrent generation spectrum conductive layer; wherein the photocurrent generation spectrum conductive layer has a first photocurrent generation spectrum covering a first band of energy levels of the electromagnetic radiation and the at least one middle insulating layer has a second photocurrent generation spectrum covering a second band of the energy levels of the electromagnetic radiation, the second band complementing the first band.

In another aspect, the sensor further includes an electrical circuit connecting the transparent conductive layer and the photocurrent generation spectrum conductive layer. In yet another aspect, the photocurrent generation spectrum conductive layer is adjacent the substrate. In a further aspect, the transparent conductive layer is adjacent the substrate. In yet a further aspect, the transparent conductive layer and the photocurrent generation spectrum conductive layer are electrically conductive at an operating temperature and the at least one middle insulating layer is electrically insulating at the operating temperature.

In another aspect, the photocurrent generation conductive layer has a smaller bandgap than the at least one middle insulating layer. In yet another aspect, the sensor of claim 1 wherein the layered structure forms a van der Waals heterostructure. In yet a further aspect, the transparent conductive layer, the photocurrent generation spectrum conductive layer and the at least one middle insulating layer are made from two-dimensional (2D) materials having a thickness in the nanometer range.

In yet another aspect, the sensor further includes a dielectric layer adjacent the transparent conductive layer; a gating layer adjacent the dielectric layer; and a gate voltage for applying a voltage to the gating layer. In another aspect, the sensor further includes a controller, the controller connected to the electrical circuit. In another aspect, the transparent conductive layer is made from graphene; the photocurrent generation spectrum conductive layer is made from black phosphorous and the at least one middle insulating layer is made from MoTe₂. In yet a further aspect, the substrate layer is made from at least one of a wafer of silicon or sapphire.

In another aspect of the disclosure, there is provided a method of acquiring a signal indicative of an intensity spectrum of electromagnetic radiation including receiving and sensing electromagnetic radiation; generating at least one photocurrent generation spectrum based on the sensed electromagnetic radiation; and transmitting a spectrum intensity signal based on the at least one photocurrent generation spectrum; wherein the at least one photocurrent generation spectrum is based on electromagnetic radiation sensed by a photocurrent generation spectrum conductive layer having a first photocurrent generation spectrum covering a first band of energy levels of the electromagnetic radiation and at least one middle insulating layer having a second photocurrent generation spectrum covering a second band of the energy levels of the electromagnetic radiation, the second band complementing the first band.

### BRIEF DESCRIPTION OF THE DRAWINGS

The foregoing and other features and advantages of the disclosure will be apparent from the following description of embodiments thereof as illustrated in the accompanying drawings. The accompanying drawings, which are incorporated herein and form a part of the specification, further serve to explain the principles of the disclosure and to enable a person skilled in the pertinent art to make and use the disclosure. The drawings are not to scale.

FIG. 1a is a schematic view of a system for acquiring a signal indicative of an intensity spectrum of electromagnetic radiation in accordance with one embodiment;

FIG. 1b is a schematic diagram of another embodiment of a system for acquiring a signal indicative of an intensity spectrum of electromagnetic radiation;

FIGS. 2a, 2b and 2c are graphs showing a photocurrent generation spectrum, an electromagnetic radiation spectrum, and an acquired spectrum, respectively;

FIG. 2d is a graph showing photocurrent intensity vs energy level;

FIG. 3a is a schematic view of another embodiment of a system for acquiring a signal;

FIG. 3b is a graph showing a spectrum associated to the operation of the system of FIG. 3a;

FIGS. 4a, 4b and 4c are graphs showing an acquired spectrum without a sample, an acquired spectrum with a sample, and a comparison between the two spectrums, respectively;

FIG. 5 is a schematic view of another embodiment of a controller;

FIG. 6a is a perspective view of a miniature broadband photodetector based on 2D materials for local spectroscopy using widefield illumination before a sample is aligned with the detector area;

FIG. 6b is a perspective view of the photodetector of FIG. 6a after a sample is aligned with the detector area;

FIG. 7a is a graph showing an absorbance spectra of BP and MoTe₂;

FIG. 7b is a graph showing photocurrent spectra at six bias voltages taken under illumination by a broadband tungsten lamp;

FIG. 7c is a band structure diagram of the heterostructure for V=−0.5 V;

FIG. 7d is a band structure of the heterostructure for V=+0.5 V;

FIG. 8a is a graph showing I-V curves of the device in dark and under illumination by focused lasers of several different wavelengths with 30 μW power and linear polarization fixed in direction generating maximum photocurrent;

FIG. 8b is a graph showing photocurrent I_{pc} as function of laser power;

FIG. 8c is a graph showing photocurrent I_{pc} as function of linear polarization angle for different laser wavelengths;

FIG. 8d is a 2D map of detector responsivity vs bias voltage and laser energy;

FIG. 8e is a graph showing External quantum efficiency (EQE) and specific detectivity (D*) vs laser energy;

FIG. 8f is a graph showing 10-90% rise and fall times of I_{pc} measured with 658 nm and 1550 nm lasers on and off;

FIG. 9a is a set of images generated by a detector showing reflection (left), 658 nm photocurrent (middle), and 2300 nm photocurrent (right) images with a 16 μm×17 μm junction area;

FIG. 9b is a set of images generated by a detector showing reflection (left), 658 nm photocurrent (middle), and 2300 nm photocurrent (right) images with a 0.8 μm×0.8 μm junction area;

FIG. 10a are images generated before and after a 2D sample transfer;

FIG. 10b is a graph showing an absorbance spectra; and

FIG. 11 is a flowchart outlining one embodiment of acquiring a signal indicative of an intensity spectrum of electromagnetic radiation.

### DETAILED DESCRIPTION

The disclosure is directed at a sensor, system and method for acquiring a signal indicative of an intensity spectrum of electromagnetic radiation. In one embodiment, the sensor includes a top conductor layer, at least one middle insulator layer and a bottom conductor layer that receives electromagnetic radiation and generates an intensity spectra based on the received radiation. In other embodiments, the sensor may include a gate layer and a dielectric layer for tuning the intensity spectra that is generated by the sensor. The system may further include a controller for communicating with the sensor to obtain the intensity spectra and may process the intensity spectra before displaying or providing the processed result to a display or user.

Since the electrical conductivity of materials can vary depending on their temperature, any expressions in the specification pertaining to electrical conductivity, such as, but not limited to, insulator and conductor, may also refer to the electrical conductivity in the conditions of operation unless otherwise indicated. Accordingly, the terms insulator or insulating layer can be understood to imply or represent “behaving as an insulator at the operating temperature” and the terms conductor or conducting layer may represent “behaving as a conductor at the operating temperature”. For example, if a given embodiment of a sensor is configured for use at room temperature, the operating temperature is room temperature.

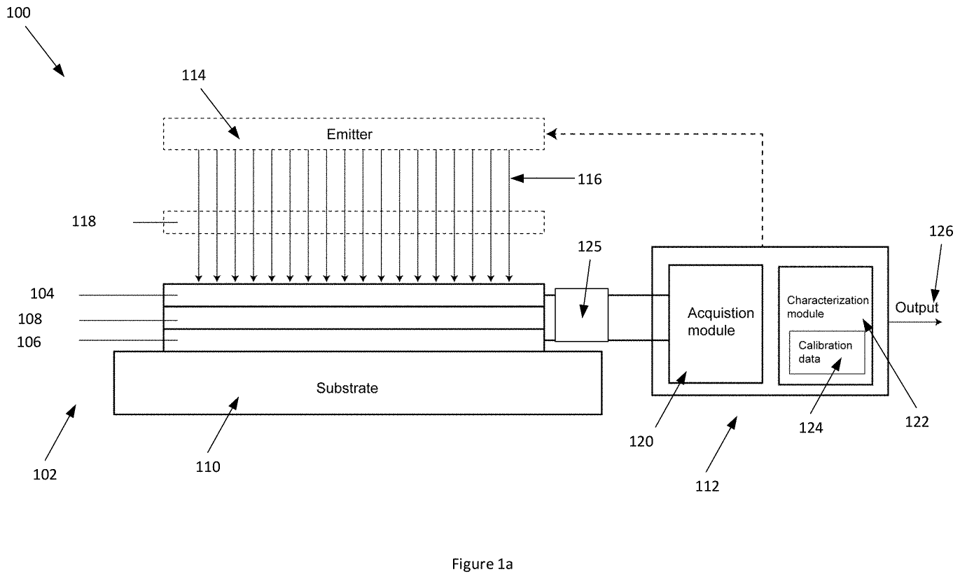

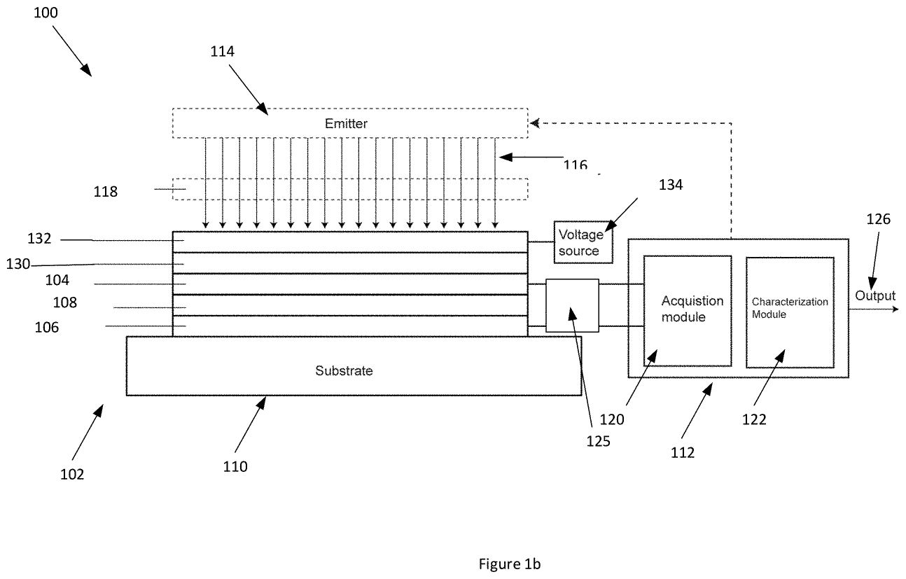

Turning to FIG. 1a, a schematic diagram of a system for acquiring a signal indicating or representing an intensity spectrum of electromagnetic radiation is shown. The system 100 includes a sensor 102 that acquires a signal indicative of an intensity spectrum of electromagnetic radiation across a band of energy levels (e.g. wavelength/frequency). In the current embodiment, the sensor 102 has a layered sensor structure including a first layer 104 (which may also be seen as a top layer), a second layer 106 (which may also be seen as a bottom layer) and at least one middle layer 108 sandwiched between the first 104 and second 106 layers. Each of the layers rest or are located on top of a substrate 110. In one embodiments, the first layer, the middle layer and the bottom layer are deposited onto the substrate. The at least one middle layer 108 may be an insulator or insulating layer that is between the top 104 and bottom 106 layers acting as conductors or conducting layers for the sensor 102.

A controller 112 communicates with an emitter 114 to transmit or direct electromagnetic radiation (shown as arrows 116) towards a sample 118 that is located between the emitter 114 and the sensor 102. In the current embodiment, the controller 112 includes an acquisition module 120 and a characterization module 122, the characterization module 122 storing, among other things, calibration data 124. The acquisition module 120 is connected to and communicates with the sensor 102 (either wirelessly or in a wired manner) to receive or retrieve electric or electrical signals from the sensor 102. The electric signals may be indicative of or associated with the spectrum generated or sensed by the sensor 102 when the electromagnetic radiation 116 contacts the sensor 102 after passing through the sample 118. It is understood that while the sample 118 is shown as being between the emitter 114 and the sensor 102, the emitter 114 and the sensor 102 may also be on the same side of the sample 118 where the sensor 102 generates the intensity spectrum based on the electromagnetic radiation that bounces off or is reflected off of the sample 118 towards the sensor 102. In one embodiment, the sensor is mounted, integrated or implanted within an electrical component and may be seen as a component of a larger electrical circuit or device. Alternatively, the sensor 102 may be a stand-alone structure that is able to communicate with the controller 112.

In one embodiment, the top layer 104 is transparent to the electromagnetic radiation 116 within an operating energy level range of the sensor 102. In another embodiment, the top conductor layer 104 may be used to collect an electrical signal with minimal or low interference.

In operation, the electromagnetic radiation 116 penetrates the sensor 102 through the first conductor 104 before passing through the insulator 108 and the second conductor 106. The insulator 108 is reactive to a first band of electromagnetic radiation and the second, or bottom, conductor 106 is reactive to a second band of electromagnetic radiation. In this description, the terms “first” and “second” are used for the purpose of differentiating reference to one band of electromagnetic radiation from reference to another band of electromagnetic radiation and do not imply any specific characteristic, feature, position or order. The expression “reactive” is used to mean that the corresponding layer or material generates a detectable photocurrent when stimulated by electromagnetic radiation above a given intensity threshold within the corresponding band of energy levels.

Contact between the electromagnetic radiation 116 and the different layers of the sensor 102 results in or causes photocurrents to be induced. The individual photocurrents (which may be seen a as photocurrent generation spectrum) or the sum of the photocurrents induced by electromagnetic radiation to which the sensor is exposed to (minus any losses) can be collected by an electrical circuit 125 connecting the first or top conductor 104 and the second or bottom conductor 106. In some embodiments, the electrical circuit 125 may communicate with the acquisition module 120 of the controller 112.

The photocurrent generation spectrum or spectrums may then be used as or seen as a signal indicative of the intensity spectrum of the electromagnetic radiation and transmitted by the sensor 102 to the acquisition module 120 such as in the form of an intensity spectrum signal. In some embodiments, depending on the characteristics of the electromagnetic radiation and/or the structure of the sensor, the controller may have to sum the photocurrent generation spectrums in areas where there is overlap between the photocurrent generation spectrums generated by the middle and bottom layers. This sum may then be used as or seen as a signal indicative of the intensity spectrum of the electromagnetic radiation and transmitted by the sensor 102 to the acquisition module 120 such as in the form of an intensity spectrum signal. The intensity spectrum signal may be an absolute value of the sum that is calculated.

In other embodiments, the electrical circuit 125 may transmit the photocurrents induced by the sensor and the controller may determine or calculate a sum of the photocurrents. The acquisition module 120 can have software functions, such as instructions stored on a non-transitory computer readable medium, that process the intensity spectrum signal to extract data from the signal. In one embodiment, the intensity spectrum signal processing may include processing the electric signal via a Fourier transformation. The controller 112 can then generate an output 126, the exact nature of which can depend on the particularities of the embodiment to which the concepts presented herein are applied. In one embodiment, the output 126 can include data representing the intensity spectrum.

Turning to FIG. 1b, a schematic diagram of another embodiment of a system for acquiring a signal indicating of an intensity spectrum of electromagnetic radiation is shown. The system of FIG. 1b is identical to the one of FIG. 1a except for the structure of the sensor 102. In the current embodiment, the sensor, or photodetector, 102 includes a dielectric layer 130 that is located on top of the top layer 104 and a gate layer 132 atop the dielectric layer 130. A voltage source 134 is connected to the gate layer 132. In some embodiments, the dielectric layer 130 and the gate layer 132 may be deposited atop the first conductor layer 104. In one embodiment, the gate layer and dielectric layer may be deposited using a mechanical transfer of 2D materials or via physical vapor deposition techniques such as, but not limited to, thermal vapor deposition.

In one embodiment, the gate layer 132 is electrically conductive and transparent to electromagnetic radiation at an operating temperature (such as the sensor operating temperature) such that the radiation can pass through the gate layer with little interference as it travels towards the other layers. In one embodiment, the gate layer 132 may be made from graphene, multiple layers of graphite or another transparent conductor such as, but not limited to, indium tin oxide. In the current embodiment, the dielectric layer 130 is electrically insulating and transparent to the electromagnetic radiation at the operating temperature. In one embodiment, the dielectric layer 130 may be made from hexagonal boron nitride, aluminum oxide or silicon oxide. In the embodiment of FIG. 1b, a gate voltage can be applied on or to the gate layer 132 to tune the photocurrent generation spectrum obtained by the acquisition module as either within a first energy band, within a second energy band or broadband (the entire energy band). In other words, the electrical signal (such as the one discussed above) that is received by the acquisition module may be pre-tuned before being transmitted by the sensor to the acquisition module. Pre-tuning of the electrical signal enables the photocurrent generation spectrum (or intensity spectrum) to be manipulated such as to provide improved images or clearer images. In some embodiments, the sign of the photocurrent generation spectrums may be opposite so the tuning may assist to align the signs. In other embodiments, the photocurrent generation spectrums can be summed and then the absolute value of the result is seen as the intensity spectrum signal.

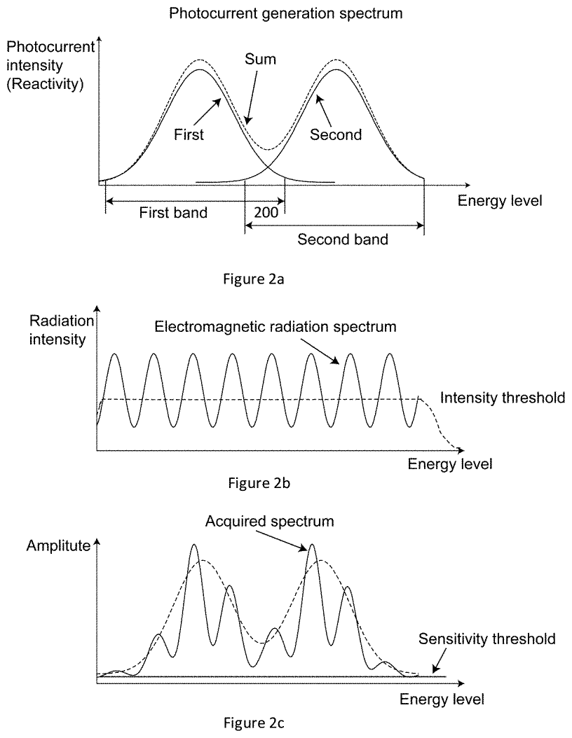

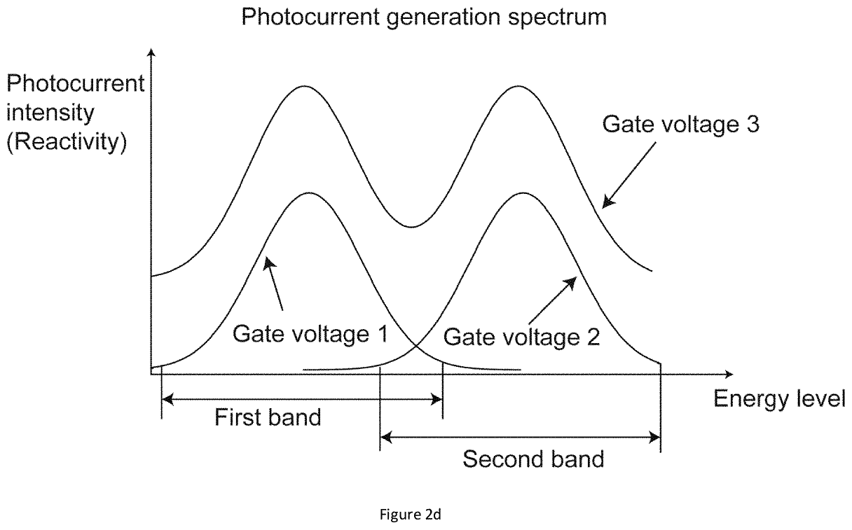

For facilitating understanding, the reactivity of the conductor layers to electromagnetic radiation is presented visually in FIG. 2a. FIG. 2a is a graph of photocurrent intensity vs energy level. The graph shows a photocurrent generation spectrum or the photocurrent intensity induced by a given intensity of electromagnetic radiation across varying energy levels as sensed by the sensor. The photocurrent generation spectrum of the bottom layer 106 (labelled as First) and the photocurrent generation spectrum of the middle layer 108 (labelled as Second) are individually presented along with a sum (labelled as Sum) of the first and second photocurrent generation spectrums. The sum of the first and second photocurrent generation spectrums may be seen as the overall intensity spectrum sensed by the sensor when it receives the electromagnetic radiation. The graph of FIG. 2a may be one that is sensed by the system of FIG. 1a.

In one mode of operation, the First and Second photo generation spectrums may be generated or sensed by the electrical circuit 125 and then summed to generate or calculate the Sum photocurrent generation spectrum. The Sum photocurrent generation spectrum may then be transmitted to the acquisition module. In another embodiment, the electrical circuit 125 may generate or sense the First and Second photocurrent generation spectrums which are then transmitted to acquisition module to sum the two photocurrent generation spectrums. The graph or portions of the graph may then form the output 126 from the controller or images based on the photocurrent generation spectrums (First, Second and/or Sum). The output 126 may then be displayed on a display or used for further processing by other processors.

As can be seen in FIG. 2a, the First and Second photocurrent generation spectrums cover corresponding first and second energy level bands. As can be seen, the energy level bands may overlap to a certain extent (such as in overlapping area 200) but do not entirely overlap each other. In other words, the energy bands over which the bottom conductor and middle insulating layers operate complement one another in that each band outspreads the other thereby covering a respective portion of the overall energy level spectrum.

The shape of the Sum photocurrent generation spectrum corresponds to a shape of the signal intensity spectrum across different energy levels for electromagnetic radiation having a constant intensity across the energy level bands. In other words, the sensor is irradiated by electromagnetic radiation having a constant intensity across both energy bands as sensed by the top and bottom layers. FIG. 2b is a schematic diagram showing a constant intensity threshold (dotted lined) over the entire energy spectrum based on the electromagnetic radiation spectrum (shown in solid lines in FIG. 2b). FIG. 2c is a graph of amplitude vs energy level showing a shape of the resulting Sum photocurrent generation spectrum after being processed via a Fourier transformation (dotted line) such as by the acquisition module. As can be seen the processed sum photocurrent generation spectrum can have shape that corresponds to the sum of the first and second photocurrent generation spectrums (FIG. 2a).

In practice, electromagnetic radiation received by the sensor will often have an intensity which varies as a function of energy level, such as exemplified in solid line in FIG. 2b and the signal acquired from the sensor will deviate from the latter shape, as shown in the solid line of FIG. 2c. Once the photocurrent generation spectrum has been characterized as a function of electromagnetic radiation intensity, one can acquire information about the actual intensity distribution of the electromagnetic radiation irradiating the sensor.

In one embodiment, this may be performed by, but is not limited to, comparing the acquired signal or spectrum to a previously characterized photocurrent generation spectrum for a known electromagnetic radiation intensity distribution, and known relationships between variations of electromagnetic radiation intensity and acquired signal intensity, made available to the characterization module in the form of calibration data.

Referring back to FIG. 2a, ranges/bands of energy levels of photocurrent generation can be defined in a given embodiment relative to a sensitivity threshold. The sensitivity threshold can depend on one or both of the intensity of the electromagnetic radiation it is intended to detect or the sensitivity of the hardware and/or software forming the system as stored in the acquisition module.

For instance, if a given embodiment of a system is intended for use with electromagnetic radiation intensity above a given minimum or low intensity (which can be established subjectively) and the system's sensitivity only allows detection when the signal intensity is above an intensity threshold (where the signal becomes distinguishable from noise or allows to reach a certain level of accuracy), the first and second bands of energy levels can be defined as spanning energy levels for which the minimum or low intensity of electromagnetic radiation will lead to a signal reaching or exceeding the intensity threshold. Accordingly, and in other words, the first and second photocurrent generation spectrum can be said to cover corresponding first and second energy level bands corresponding to regions where the photocurrent generation for a given intensity of electromagnetic radiation will lead to a photocurrent response above a detectability threshold.

Turning to FIG. 2d, a graph showing photocurrent intensity vs energy level for the system of FIG. 1b is shown. As can be seen in FIG. 2d, the photocurrent generation spectrum can be tuned by the gating layer to generate improved First (Gate Voltage 1), Second (Gate Voltage 2) and Sum (Gate voltage 3) photocurrent generation spectrums when compared with system of FIG. 1a.

Referring back to either FIG. 1a or 1b, the photocurrent generation spectra sensed by the top 104 and bottom 106 layers depends on both the nature and the configuration of the material used for the top and bottom layers.

In one embodiment, materials exhibiting “2D” characteristics are used. Examples of materials with “2D” characteristics may be defined as materials that have a single to a few atomic layers (e.g. 1 to 10) but at a given number of layers depending on the nature of the material, the material can begin to lose its “2D” physical properties at the interface (between the top or bottom layer and an adjacent layer) such as their bandgap, and begin to act as a bulk state. A layered structure of 2D materials can be referred to as a van der Waals heterostructure. Current materials include, but are not limited to, graphene or few layer graphite, 2H-MoTe₂, WS₂, MoS₂, BP, and black arsenic phosphorus. In another embodiment, other materials having similar bandgap characteristics are contemplated whereby predetermined bandgap relationships between the layers is maintained. The available selection can be particularly, and further limited when additional characteristics are imposed, such as, but not limited to, insulation capacity or electrical conductivity at a given operating temperature (particularly room temperature).

In one embodiment, the materials for the sensor layers may be selected based on the selected materials having photocurrent generation bands which complement one another and such that they may extend the overall operating band. Moreover, the materials selected for the photocurrent generation sensor can include an insulator in addition to a conductor when the insulator is sandwiched with another conductor. The other conductor can be transparent to electromagnetic radiation in a manner to reduce or minimize losses.

In one sensor embodiment, the material of the reactive conductor (or bottom conductor layer) may have a first band gap, and the material of the reactive insulator (or middle layer) may have a second band gap, where the second band gap is larger than the first band gap. The material for the transparent conductor (or top layer) can be a material that does not have an energy gap.

In one specific example embodiment, thin, e.g. “2D”/few atomic layer thin layers, of black phosphorous were used for the reactive conductor (bottom layer), MoTe₂ was used for the reactive insulator (or middle layer), and graphene, as a transparent conductor was used for the top layer. In use, the photocurrent generation response band of MoTe₂ extended from visible wavelengths to ultraviolet, whereas the black phosphorous photocurrent generation response band covered infrared due to its smaller band gap, leading to a broadband response spectrum. Moreover, each of MoTe₂, black phosphorous and graphene can offer suitable characteristics at room temperature.

For the top layer, graphene in a thickness of a few atomic layers was found suitable to form a transparent conductor. As each atomic layer of graphene can absorb about 2% of electromagnetic radiation, even with a few atomic layers of graphene, the resulting top layer can be considered transparent. In one embodiment, the expression “transparent” can be applied to a material allowing a sufficient intensity of light through to allow the generation of a detectable signal with the other layers of the sensor structure. The generation of the detectable signal may also depend on the acquisition equipment and the intensity of the electromagnetic radiation. Transparency above 50%, above 75%, above 85% can be suitable in some embodiments, but in some embodiments it is not excluded that transparency below 50% could be suitable and allow suitable detectability. A lesser amount of atomic layers in thickness may be preferred from the point of view of better transparency, but on the other hand, more atomic layers may be preferred from the point of view of improved conductivity.

For the middle layer, MoTe₂ can be considered a 2D semiconductor material that may also act as an insulator at room temperature. The absolute value of electrical conductivity corresponding to the conductors may not be as important a feature as its relative value compared to the insulating capacity of the insulator. In the case of graphene as a top layer covering a 2D semiconductor middle layer of MoTe₂, 1 to 3 atomic layers of graphene can be suitable in some embodiments. In an embodiment, the transparent conductor layer is less than 5 nm.

It will be understood that in alternate embodiments, other materials, or another specific combination of materials may be contemplated. For example, indium tin oxide (ITO) may be suitable for use instead of graphene in some embodiments. Suitable materials may also be determined from simulation rather than experiment to limit costs associated to identifying alternatives. Other transition metal dichalcogenides, such as, but not limited to, MoS₂, MoSe₂, WS₂, or WSe₂ may be used for the middle layer in an alternate embodiment. The material for the substrate which supports the layered heterostructure can also vary from one embodiment to another. Examples of substrate materials may include, but are not limited to, silicon, fused silica, or sapphire wafers.

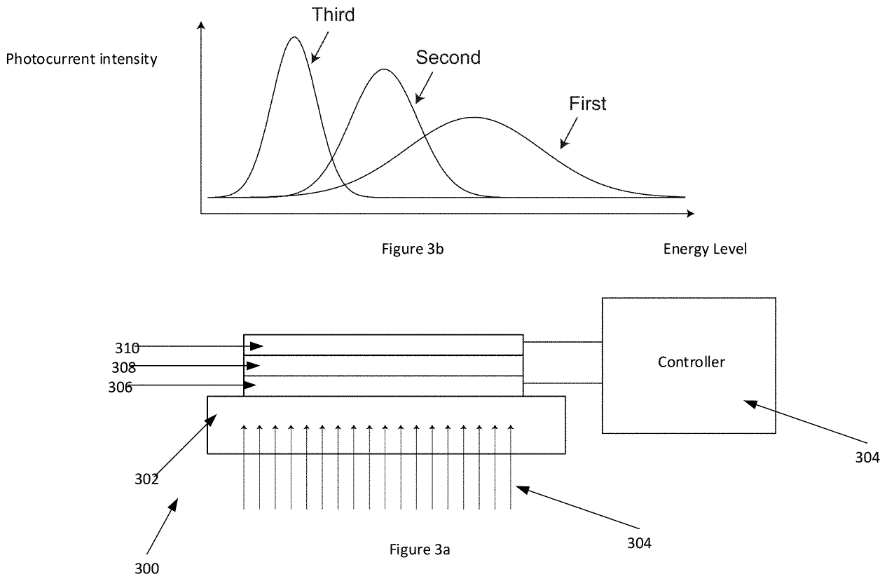

Various alternate configurations are possible, and materials for different layers can take the configuration of an embodiment into consideration. For instance, and as exemplified in FIG. 3a, in one embodiment, the sensor 300 includes a substrate 302, such as glass, that is transparent to the electromagnetic radiation 304 whereby the electromagnetic radiation can propagate across the substrate. Atop the substrate 302 is a first conductor layer 306 (similar to the transparent conductor layer of FIG. 1a). In this embodiment, the transparent conductor layer 304 can be directly supported by a corresponding face of the substrate 302, with a reactive insulator 308 and reactive conductor 310 stacked onto the conductor layer 306. The sensor 302 communicates with a controller 312.

In another embodiment, the sensor 302 may include at least two middle layers 308 that are stacked against one another and sandwiched between the two conductive layers. The at least two middle layers can be semiconductors acting as reactive insulators. In an embodiment with two middle layers, one of the middle layers, which may be directly in contact with the transparent conductor layer, can be of a first material exhibiting a first band gap, and a first photocurrent generation spectrum and the second middle layer can be of a second material exhibiting a second band gap, smaller than the first, and a second photocurrent generation spectrum. The reactive conductor layer can have a third band gap and generates a third photocurrent generation spectrum. In some embodiments, the second band gap can be smaller than the first band gap, and the third band gap can be smaller than the second band gap. An example of a photocurrent generation spectrum for this embodiment is shown in FIG. 3b.

Referring to FIG. 3a, in one embodiment, the system can be used in a standalone manner in order to acquire a signal indicative of an intensity spectrum of incoming electromagnetic radiation. In other words, in such an embodiment, the electromagnetic radiation itself can be considered to be a sample to be analyzed.

For some embodiments of the system, the emitter may transmit a controlled source of actively generated electromagnetic radiation, such as one having a given intensity distribution spanning the energy bands of the photocurrent generation spectrums of any and/or all photocurrent generating layers, and can rather be used to characterize solid samples such as, but not limited to, samples of thin material.

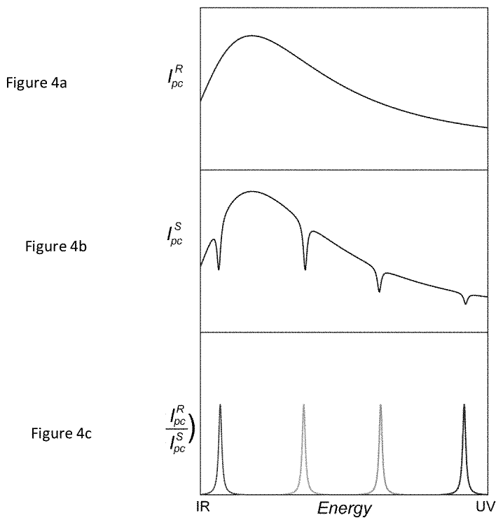

For instance, the system can be calibrated by acquiring the signal resulting from irradiating the sensor with the controlled source of electromagnetic radiation directly, i.e. without any sample present, and the resulting intensity spectrum can be stored as calibration data for use as a reference. In one embodiment, the reference spectrum is represented in FIG. 4a. The signal resulting from irradiation with the same controlled electromagnetic radiation source, but when the emitted electromagnetic radiation is intersected by a sample positioned between the source and the sensor and the resulting intensity spectrum is shown in FIG. 4b. By comparing the reference spectrum to the spectrum affected by the sample, one can determine a spectral signature specifically associated to the sample. FIG. 4c shows the logarithmic ratio between the reference spectrum and the spectrum with (I_{pc}^{s}) and without (I_{pc}^{R}) the sample and can be considered a spectral signature of the sample. In one embodiment, local absorbance spectrum of the sample may be obtained from a logarithmic ratio of the two photocurrents (log(I_{pc}^{R},I_{pc}^{S})).

Moreover, as will be illustrated by the embodiment presented below, in some embodiments, a greater sensitivity may be achieved when an electrical bias, e.g. a DC bias, is applied across the layers when the signal is acquired. FIG. 5 provides a schematic diagram of another embodiment of a controller 500. The controller 500 includes an acquisition module 502, a characterization module 504 (which may store calibration data 506). The controller 500 further includes a DC bias generator 508, and the DC bias can be applied using the same electrical leads as those used to acquire the signal from the sensor and a source control module 510.

In some embodiments, the hardware and any software elements performing functions associated to the operation of the system may be implemented within the controller, and the individual elements associated to corresponding functions can be referred to as modules. The controller can be embodied as some form or another of one or more computers, depending on the embodiment, and can potentially include one or more of the acquisition module, the characterization module, the DC bias generator module, and the electromagnetic radiation source control module. In different embodiments, the different functions can be local, remote, or distributed with respect to the sensor. The expression “computer” as used herein is not to be interpreted in a limiting manner but in a broad sense to generally refer to the combination of some form of one or more processing units and some form of non-transitory memory system accessible by the processing unit(s). The use of the expression “computer” in its singular form as used herein includes within its scope the combination of two or more computers working collaboratively to perform a given function. Moreover, the expression “computer” as used herein includes within its scope the use of partial capacities of a processing unit of an elaborate computing system also adapted to perform other functions. Similarly, the term controller is not to be interpreted in a limiting manner but rather in a general sense of a device, or of a system having more than one device, performing the function(s) of controlling one or more device such as, but not limited to, an electronic device or an actuator.

It will be understood that the various functions of a computer or of a controller can be performed by hardware or by a combination of both hardware and software. For example, hardware can include logic gates included as part of a silicon chip of the processor. Software can be in the form of data such as computer-readable instructions stored in the memory system. With respect to a computer, a controller, a processing unit, or a processor chip, the expression “configured to” relates to the presence of hardware or a combination of hardware and software which is operable to perform the associated functions.

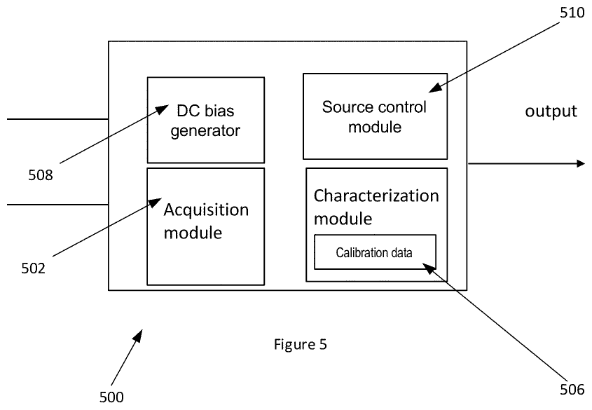

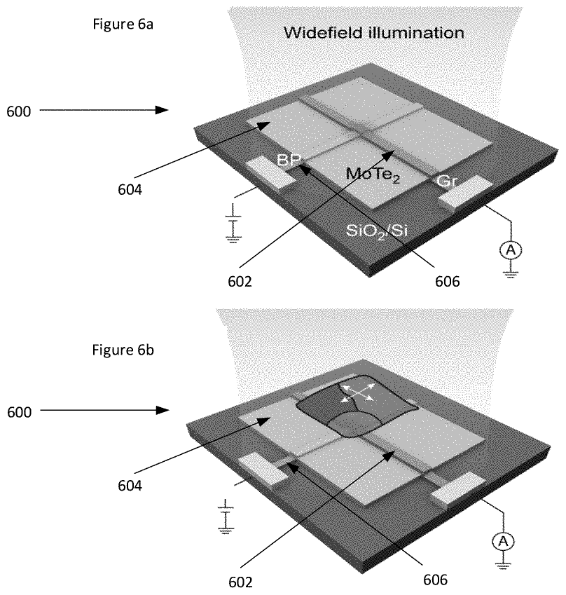

An example embodiment of the disclosure is shown in FIG. 6a which is a schematic representation of a spectroscopy sensor with a measurement circuit. In the specific embodiment, the spectroscopy sensor 600 includes a transparent top electrode, or top conductor 602 made from a few (such as from 1 to 5) layers of graphene (Gr); a middle, semiconducting or insulating layer 604 made from MoTe₂ and a bottom electrode or bottom conductor layer made from small-bandgap black phosphorus (BP) 606. Use of MoTe₂ allows the middle layer 604 to absorb light above about 0.9 eV energy and use of BP allows the bottom electrode 606 to serve both as a bottom conductor and absorber for light energy down to about 0.3 eV.

In the current embodiment, the heterostructures may be assembled by dry-transfer within a nitrogen-filled glovebox and covered by a thin insulating layer of hexagonal boron nitride (hBN), which is transparent to light below 5.9 eV, to protect the BP layer 606 from degradation in an ambient measurement environment. In this embodiment, the hBn layer provides protection fo the other layers within the sensor structure. An example of the absorbance spectra of this sensor embodiment is plotted in FIG. 4a. While BP is an excellent photodetector in the IR range, the combination with MoTe₂ layer 602 sandwiched between the BP layer 606 and the top transparent conductor 602 allow for a continuous spectral response from the mid-infrared (MIR) to the near-ultraviolet (NUV). While any MoTe₂ and BP flake thickness larger than approximately 2 nm and approximately 10 nm, respectively, will yield a bandgap close to that of bulk crystal, a sensor including approximately 10 nm thick MoTe₂ and approximately 17 nm thick BP can result in a higher responsivity for the sensor. This specificity may not be required in all embodiments. Moreover, in an alternate embodiment, a larger bandgap semiconductor material may be used instead of MoTe₂ which may leave a gap in the response spectrum but is still operable for acquiring a signal indicative of an intensity spectrum of electromagnetic radiation.

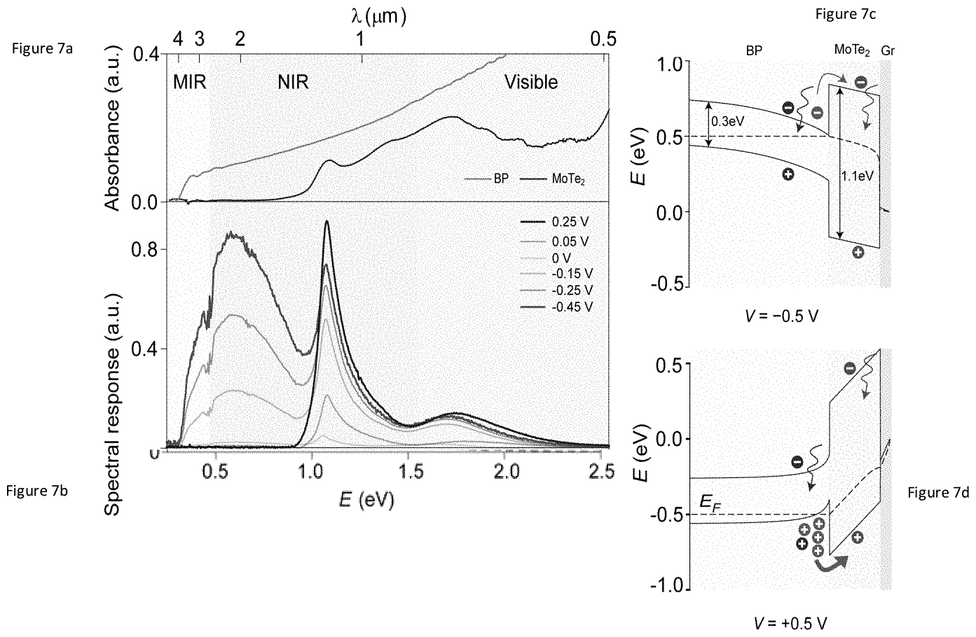

Turning to FIG. 7b, the photocurrent spectral response of a sensor device is shown. For the testing, the sensor device had a junction area of 15 μm×18 μm at several different voltage biases. The spectra were acquired using a Fourier transform infrared (FTIR) spectrometer acting as an acquisition module, under illumination by a tungsten lamp. At zero bias, the overall photoresponse is relatively weak. Upon increasing positive voltage between the BP layer 606 and the Gr layer 602, the response in the near-IR (NIR) and visible range is continuously increased, but no response is observed below 0.3 eV. The two peaks at 1.06 eV and 1.72 eV correspond to the A and A′ excitons in the MoTe₂ layer 604. Upon increasing negative voltage, the response from the MoTe₂ layer 604 is similarly increased; however, the response from the BP layer 606 at lower energies increases as well. In particular, the MoTe₂ A exciton peak picks up where the BP response decays. The net result is a continuous spectral response from the MIR at 0.3 eV to the visible when a small negative voltage is applied to the sensor. The decay at high energies is attributed to the low intensity of the tungsten source. Depending on the embodiment and context of use, the sensor can exhibit significant responsivity up to approximately 3 eV, yielding a spectral range of at least a full decade in energy.

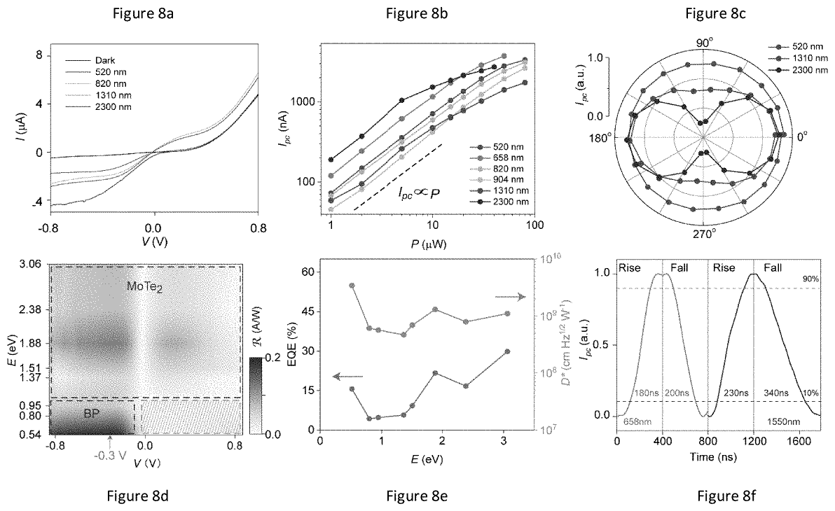

The bias asymmetry of the response at low photon energy is a manifestation of the offset band alignment of the heterostructure shown in FIGS. 7c and 7d which can be understood through characterization and theoretical modeling of the device transport properties. Without illumination, the I-V characteristics exhibit diode-like rectifying behavior, as can been seen in FIG. 8a for the same 15 μm×18 μm device. No substantial photocurrent is observed for IR light at a positive value for V.

Using finite element numerical simulations of the heterostructure, a close fitting between the calculated and experimentally observed transport characteristics can be achieved. A series of band alignments and carrier concentration profiles for various bias conditions are then extracted. At zero and forward bias (V≥0), the BP/MoTe₂ interface forms a hole-accumulation region owing to the intrinsically p-doped BP. These holes are the dominant carrier concentration of the entire heterostructure, and so contribute to relatively large current levels for V>0 after surmounting the MoTe₂ barrier. Under reverse bias (V≤−0.3V), however, a comparably smaller population of electrons accumulate at the same interface, leading to relatively less current. This asymmetry can be directly observed in the representative band diagrams shown in FIGS. 7c and 7d for V=±0.5 V, and is further schematized by the dark carriers and arrows in gray.

The wavelength-dependent photocurrent generated by the system is substantial, but also distinct for different bias directions, which is consistent with the bias dependence of the full photocurrent spectrum (FIG. 7a). FIG. 8a also shows the I-V characteristics of the same device under illumination by focused lasers of several different wavelengths with the same power and polarization. When a visible (λ=520 nm) or NIR (λ=820 nm) laser is used, whose energy is larger than the MoTe₂ bandgap energy, a large increase in device current with light, or photocurrent I_{pc} is observed. As photocarriers are predominantly generated in the upper MoTe₂ layer for this photon energy regime, both forward and reverse bias lead to barrierless transport and relatively efficient collection of these carriers, and so I_{pc}>I_{dark} for nearly all V.

When IR lasers (λ=1310, 2400 nm) are used, large photocurrent flows only under reverse bias, and not forward bias. This unique property of the sensor can also be qualitatively understood in terms of the bias asymmetry of carriers accumulated at the BP/MoTe₂ interface. In general, the photocurrent is expected to be suppressed if the number of dark carriers greatly exceed that of the photo-generated carriers. As the interfacial carrier concentration under forward bias is significantly greater than that under reverse bias, I_{pc}<<I_{dark} for V≥0 when the photon energy is below the MoTe₂ bandgap. This bias asymmetry is illustrated by the red carriers and arrows in FIGS. 7c and 7d. In short, to obtain the broadest spectral photoresponse, BP must be negatively biased against Gr in the example sensor geometry, and the latter method of operation will be implied unless explicitly otherwise indicated below.

To determine the optimal light excitation and bias conditions at which to evaluate the various performance metrics of the 15 μm×18 μm photodetector (responsivity, quantum efficiency, detectivity, and response speed), the laser power dependence of I_{pc} for various incident wavelengths is shown to be linear below approximately 5 ρW for all wavelengths, but gradually saturates with increasing power. Subsequent measurements were made to be within the linear regime.

FIG. 8c displays normalized I_{pc} as a function of the linear polarization angle of the laser for three wavelengths. For λ=2300 nm(0.52 eV), light absorption is almost solely attributed to BP, which is known to be stronger (weaker) for polarization along the armchair (zigzag) direction. The maximal I_{pc} lobes were identified as the BP armchair angle. For λ=520 nm (2.4 eV), I_{pc} is almost fully symmetric, which indicates that the photocarriers are mainly generated by light absorption from MoTe₂. For λ=1315 nm (0.95 eV), an intermediate level of asymmetry was observed, suggesting that both BP and MoTe₂ contribute to the photoresponse.

For the polarization angle yielding a maximum or high I_{pc}, FIG. 8d shows the device responsivity ( [symbol] ) as a function of laser energy and bias voltage in a 2D false-color plot where the regions where BP or MoTe₂ primarily contribute to the photoresponse are boxed. In this Figure, the different photoresponse regions are boxed by dashed lines. The −0.3V arrow marks the voltage where quantum efficiency, detectivity, and rise/fall time are evaluated. Photocurrent at high energies is mainly due to MoTe₂ absorption at all biases, with an optimum [symbol] of −0.15 NW at 1.88 eV and −0.23 V. The low energy response at negative bias is due to BP and exhibits [symbol] as high as −0.2 NW at 0.54 eV and −0.3 V. There is also an inaccessible, or insubstantial, region (hashed area in FIG. 8d) at positive bias and low energy. While the spectral response is highly tunable with voltage, it appears a single negative bias near −0.3 V (marked by the red arrow) can be applied to reach peak responsivity for all wavelengths. This unique feature of our photodetectors allows us to access their full spectral range without changing biasing conditions as is required for some other detector systems. It was noted that the optimal voltage is dependent on the incident light power.

FIG. 8e shows the external quantum efficiency (EQE= [symbol] hc/(λe), where h is Planck's constant, c is speed of light in vacuum, and e is the electron charge) and specific detectivity (D*= [symbol] A^{1/2}/s_{I}^{1/2}, where A is the detector area and S_{I} is the current noise spectral density averaged over the electrical bandwidth), obtained at −0.3 V as a function of laser energy. In the MIR (0.52 eV) and NUV (3 eV), the EQE is 15% and 30%, respectively, while the corresponding D* is 3.4×10⁹ and 1.1×10⁹ cm Hz^{1/2}W⁻¹, which is comparable to that of commercial IR detectors based on InAsSb or InSb.

The response of I_{pc} to illumination on and off for two laser energies in the IR and visible are shown in FIG. 8f. While the rise and fall times are all similar, the fastest response obtained is τ is approximately 180 ns, which corresponds to an electrical bandwidth of 0.35/τ=1.9 MHz. It is noted that this speed is the fastest reported for photodetectors with comparable spectral range. Overall, the detectors of the disclosure may achieve extremely broadband detection together with high sensitivity and fast response without the need for cryogenic cooling.

A key advantage of the disclosure is that the junction area size can be easily controlled to be smaller than the diffraction limit for IR radiation, enabling it for local spectroscopic measurements. In order to confirm that the active region is localized within the overlap area between the three materials, spatially resolved photocurrent measurements by raster-scanning the focused laser were performed.

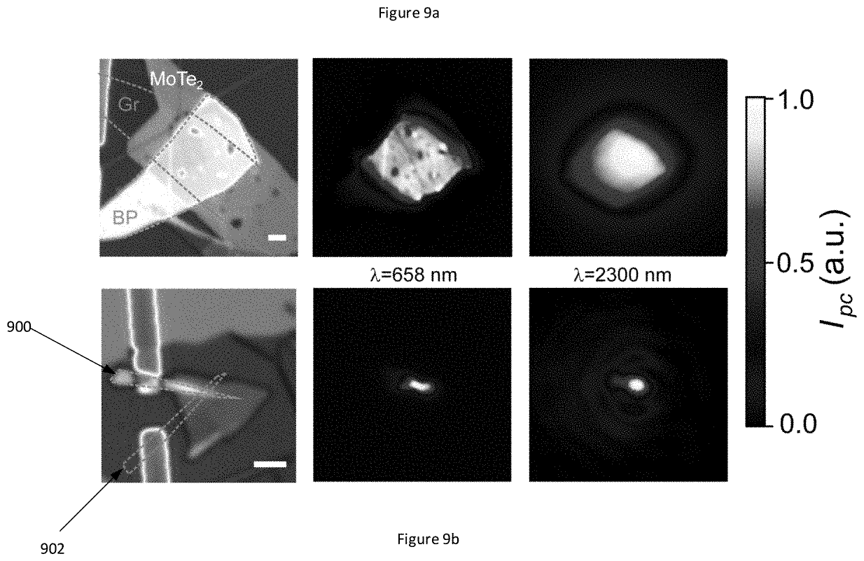

FIGS. 9a and 9b show photocurrent imaging of two devices with different junction sizes (16 μm×17 μm for FIGS. 9a and 0.8 μm×0.8 μm for FIG. 9b), each taken using two laser wavelengths in the visible (658 nm) and IR (2300 nm). In FIG. 9b, a first dashed section 900 outlines the BP response and a second dashed section 902 outlines the Gr response. Some of the fringes in IR photocurrent are due to the use of a reflective objective.

The laser reflection images are shown in the panels on the left in grayscale. For the 658 nm laser, the spot size formed by the objective lens is approximately 2 μm, which is larger than the junction area of the smaller device. Nonetheless, the strongest signal is clearly detected to originate from the overlap region of both, although there is a small decay outside the junction along the BP layer 606. The small features observed in the junction of the larger device correspond to unintended non-uniformities (wrinkles, bubbles, etc.) created during the fabrication process and can be recognized in the optical image as well. For the 2300 nm laser, photocurrent images are taken using a reflective objective, which produces a series of circular fringes around the main focal spot. The bright features outside of the junction were attributed to imaging artifacts and not to the detectors themselves.

Further photocurrent spectra of both devices using the FTIR were taken. While the MIR response is slightly reduced in the device with smaller area, both produce a substantial photocurrent response down to 0.3 eV. These results establish that the photodetector junction of the disclosure can still be responsive even when the size is scaled five times below its longest detectable wavelength of 4.1 μm.

When embodied as sub-wavelength photodetectors, the sensor can be sensitive enough to perform absorption spectroscopy on samples locally across the entire spectral range of detectivity. Several small-area devices with junction sizes between 0.8 μm×0.8 μm and 3 μm×3 μm can be illuminated using a slightly focused tungsten lamp forming a relatively large (approximately 3 mm) diameter spot centered on the active area. Photocurrent spectra can be taken before and after transferring two different 2D materials (Ta₂NiSe₅ and WSe₂) on top for absorbance measurements.

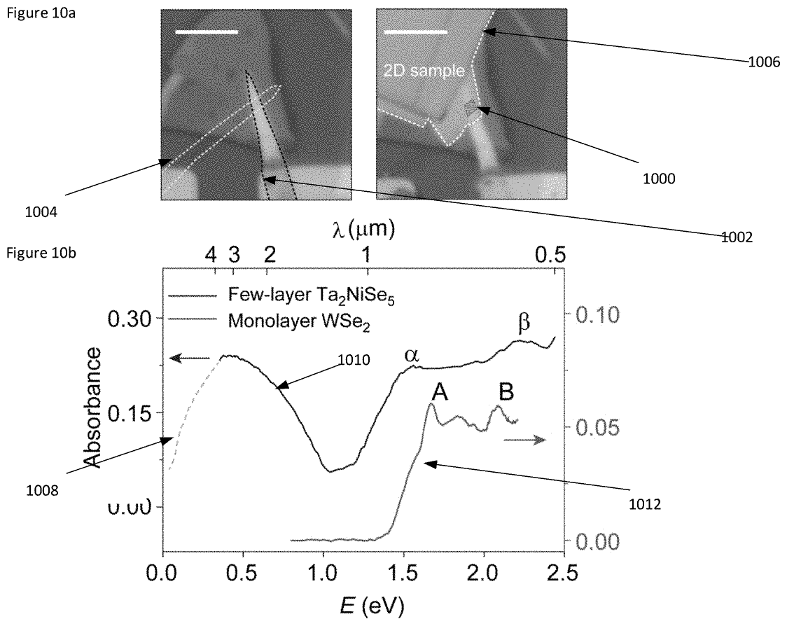

FIG. 10a shows optical images of a particular device before and after transfer of thin Ta₂NiSe₅, with the junction region marked in red. The local spectroscopy capability of the disclosure on 2D samples before (left) and after (right) 2D sample transfer are shown. In testing, a broadband tungsten source was focused by a parabolic mirror to an approximately 3 mm spot centered on the device junction marked by the shaded area 1000. Dashed lines 1002, 1004 and 1006 outline the BP layer, the Gr layer, and the 2D sample, respectively.

The Ta₂NiSe₅ flake is nonuniform and has different thicknesses in different regions. However, an absorbance spectrum on the part of the Ta₂NiSe₅ flake directly above the detector can be obtained. With FIG. 10b, an absorbance spectra of thin Ta₂NiSe₅ and monolayer WSe₂ are shown. Dashed line 1008 provides a guide-to-eye for the Ta₂NiSe₅ spectrum expected below 0.3 eV. The photodetector can both resolve features down to a single atomic layer and yield broadband sensitivity down to 0.3 eV or 4.1 μm, larger than the width of the junction. The top line 1010 in FIG. 10b is a representative spectrum of 15-nm-thick Ta₂NiSe₅ taken in this manner. The α and β peaks at 1.5 eV and 2.2 eV, respectively, have been previously identified in bulk crystals. Importantly, the peak in the MIR at approximately 0.39 eV (3180 nm) was able to be detected. A similar absorbance spectrum of monolayer WSe₂ was obtained using this technique and is shown in the bottom trace or line 1012 of FIG. 10b. Even though the overall absorbance is relatively low (approximately 0.07 maximum), the direct bandgap absorption onset edge is clearly seen at ˜1.5 eV and the A and B excitons at 1.6 eV and 2.1 eV can be identified as well. The sensor embodiment is thus able to resolve absorption features down to the monolayer limit.

The disclosure is directed at a sensor based on 2D van der Waals heterostructures with high broadband detectivity from the MIR to NUV and fast response times which can be operable at room temperature. The active device area can be scaled down to 0.6 μm² and still sense IR radiation with wavelength longer than 4 μm. Furthermore, the sensitivity is high enough to perform absorption spectroscopy on monolayer flakes under widefield illumination. The sensor may represent a low cost option for local IR measurements beyond the diffraction limit.

In some embodiments, by replacing BP with black arsenic phosphorus, the longest detectable wavelength may potentially be expanded to 8.2 μm. Using nanofabrication, one may be able to decrease the size of the junction further, down to the nanoscale. Combined with large-scale films grown by chemical vapor deposition, one may even be able to develop dense pixel arrays using the heterostructure of the disclosure to perform hyperspectral imaging with super-resolution across a decade in energy in the future

The sensor based on 2D materials with multiple bandgaps can be sensitive to radiation across a decade in energy from the mid-IR (MIR) to near-UV (NUV), or 0.3 to >3 eV, at room temperature. The photocurrent spectrum can be further tunable with bias voltage and can be optimized to reach peak external quantum efficiencies of 15% and 30% in the MIR and NUV, respectively, with corresponding specific detectivities of 3.4×109 and 1.1×109 cm Hz½ W-1. The device response time can be ˜200 ns. The overall device behavior can be understood via a numerical finite element analysis model, and identifying the bias-voltage-dependent band diagrams and carrier concentrations. The active area can be made far smaller than the diffraction limit for the lowest energy of detectable IR radiation, enabling such devices for direct measurements of local optical properties.

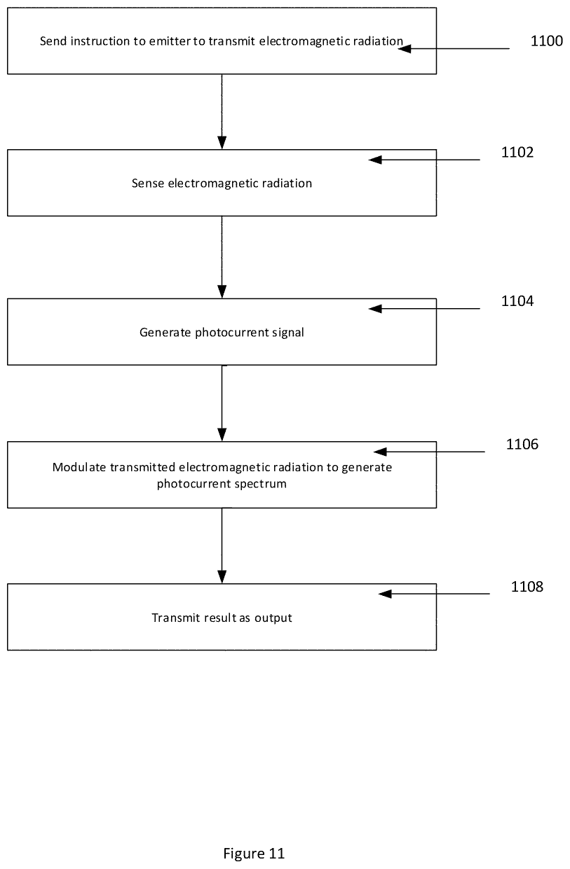

Turning to FIG. 11, a method of acquiring a signal indicative of an intensity spectrum of electromagnetic radiation is shown. Initially, a controller may send instructions to an emitter to transmit electromagnetic radiation towards a sensor structure (1100). In some embodiments, there may be sample between the emitter and the sensor structure and, in other embodiments, there may be no sample between the emitter and the sensor structure. Depending on the setup of the system, this may be part of the method or the method may commence with the sensing of electromagnetic radiation by the sensor structure.

The electromagnetic radiation is then received and sensed by the sensor structure (1102). In one embodiment, as discussed above, the electromagnetic radiation passes through the top transparent conductive layer, the at least one middle insulating layer and the bottom or photocurrent generation spectrum conductive layer to the substrate. Individual photocurrent generation spectrums are then generated by the middle insulating layer and the photocurrent generation spectrum conductive layers (1104). In some embodiments, a gating voltage may be applied to a gating layer to tune the photocurrent generation spectrums before they are acquired.

The individual photocurrent generation spectrums are then processed (1106). In one embodiment, the photocurrent generation spectrums may be processed by a FTIR spectrometer to sum the photocurrent generation spectrums. In another embodiment, the processing may be to calculate an absolute value for the photocurrent generation spectrums. In yet another embodiment, the processing may be performed by an electrical circuit that connects layers of the sensor structure together or via a controller that receives the individual photocurrent generation spectrums. The result may then be transmitted as an output (1108).

While various embodiments have been described above, it should be understood that they have been presented only as illustrations and examples of the present disclosure, and not by way of limitation. It will be apparent to persons skilled in the relevant art that various changes in form and detail can be made therein without departing from the spirit and scope of the disclosure. Thus, the breadth and scope of the present disclosure should not be limited by any of the above-described exemplary embodiments but should be defined only in accordance with the appended claims and their equivalents. It will also be understood that each feature of each embodiment discussed herein, and of each reference cited herein, can be used in combination with the features of any other embodiment. All patents and publications discussed herein are incorporated by reference herein in their entirety.

As can be understood, the examples described above and illustrated are intended to be exemplary only. The scope is indicated by the appended claims.

What is claimed is:

1. A sensor for acquiring a signal indicative of an intensity spectrum of electromagnetic radiation, the sensor comprising:
a substrate layer; and
a layered sensor layer atop the substrate layer;
wherein the layered sensor layer includes:
a transparent conductive layer;
a photocurrent generation spectrum conductive layer; and
at least one middle insulating layer located between the transparent conductive layer and the photocurrent generation spectrum conductive layer;
wherein the photocurrent generation spectrum conductive layer has a first photocurrent generation spectrum covering a first band of energy levels of the electromagnetic radiation and the at least one middle insulating layer has a second photocurrent generation spectrum covering a second band of the energy levels of the electromagnetic radiation, the second band complementing the first band.

2. The sensor of claim 1 further comprising an electrical circuit connecting the transparent conductive layer and the photocurrent generation spectrum conductive layer.

3. The sensor of claim 1 wherein the photocurrent generation spectrum conductive layer is adjacent the substrate.

4. The sensor of claim 1 wherein the transparent conductive layer is adjacent the substrate.

5. The sensor of claim 1 wherein the transparent conductive layer and the photocurrent generation spectrum conductive layer are electrically conductive at an operating temperature and the at least one middle insulating layer is electrically insulating at the operating temperature.

6. The sensor of claim 1 wherein the photocurrent generation conductive layer has a smaller bandgap than the at least one middle insulating layer.

7. The sensor of claim 1 wherein the layered structure forms a van der Waals heterostructure.

8. The sensor of claim 7 wherein the transparent conductive layer, the photocurrent generation spectrum conductive layer and the at least one middle insulating layer are made from two-dimensional (2D) materials having a thickness in the nanometer range.

9. The sensor of claim 1 further comprising
a dielectric layer adjacent the transparent conductive layer;
a gating layer adjacent the dielectric layer; and
a gate voltage for applying a voltage to the gating layer.

10. The sensor of claim 2 further comprising a controller, the controller connected to the electrical circuit.

11. The sensor of claim 1 wherein the transparent conductive layer is made from graphene; the photocurrent generation spectrum conductive layer is made from black phosphorous and the at least one middle insulating layer is made from MoTe₂.

12. The sensor of claim 1 wherein the substrate layer is made from at least one of a wafer of silicon or sapphire.

13. A method of acquiring a signal indicative of an intensity spectrum of electromagnetic radiation comprising:
receiving and sensing electromagnetic radiation;
generating at least one photocurrent generation spectrum based on the sensed electromagnetic radiation; and
transmitting a spectrum intensity signal based on the at least one photocurrent generation spectrum;
wherein the at least one photocurrent generation spectrum is based on electromagnetic radiation sensed by a photocurrent generation spectrum conductive layer having a first photocurrent generation spectrum covering a first band of energy levels of the electromagnetic radiation and at least one middle insulating layer having a second photocurrent generation spectrum covering a second band of the energy levels of the electromagnetic radiation, the second band complementing the first band.
